(19) United States
(12) Patent Application Publication
(10) Pub. No.: US 2026/0254200 A1
(43) Pub. Date: Aug. 27, 2026

(54) TWO-DIMENSIONAL PERIODICALLY INDEX-COUPLED FABRY PEROT LASER ("2D PIC-FL")

(71) Applicant: nLIGHT, Inc., Camas, WA (US)

(72) Inventor: Manoj Kanskar, Portland, OR (US)

(21) Appl. No.: 19/548,196

(22) Filed: Feb. 24, 2026

Related U.S. Application Data
(60) Provisional application No. 63/763,111, filed on Feb. 25, 2025.

(51) Int. Cl. H01S 5/12

(52) U.S. Cl. CPC H01S 5/1215

(57) ABSTRACT

A two-dimensional periodically index-coupled Fabry Perot laser includes a substrate, a n-cladding layer disposed atop the substrate, a n-waveguide layer disposed atop the n-cladding layer, a p-waveguide layer disposed atop the n-waveguide layer, a quantum well disposed between the n-waveguide layer and the p-waveguide layer, a p-cladding layer disposed atop the p-waveguide layer, a p-contact layer disposed atop the p-cladding layer, and a two-dimensional grating layer is disposed between the p-cladding layer and the p-contact layer. The two-dimensional grating layer comprises a plurality of holes arranged in a pattern with a predetermined grating period. The two-dimensional grating layer defines a first grating area beneath the p-contact layer. The two-dimensional grating layer defines a second grating area surrounding the first grating area.

### CROSS-REFERENCE TO RELATED APPLICATION(S)

This application relies on and claims priority benefit of U.S. Provisional Application No. 63/763,111, filed Feb. 25, 2025, the entire contents of which are incorporated herein by reference.

### FIELD OF THE INVENTION

The present disclosure relates to a construction for a diode laser. More specifically, the present invention concerns a construction for a two-dimensional periodically index-coupled Fabry Perot Laser (“2D PIC-FL”).

### BACKGROUND OF THE INVENTION

It is commonly understood that high power broad area lasers are limited in their power due to multi-mode operation and filamentation formation due to gain-index coupling.

In particular, it is understood that the output beam of a broad area laser is a multimode output that is diffraction limited by more than 20 times.

Single mode lasers based on a ridge waveguide architecture (e.g., slab-coupled optical waveguide lasers (“SCOWL”), ridge waveguide lasers (“RWG”), etc.) are limited to a few watts of output power due to facet power loading which can lead to catastrophic optical mirror damage (“COMD”) when operated at higher output power.

Such prior art lasers also are understood to lack suitable efficiency, because the series resistance associated with such lasers is larger by >5×, compared to broad area lasers, due to the very narrow device geometry used for single mode operation.

In view of these deficiencies, a need has developed for broad area semiconductor lasers with emitter widths that are much larger than a conventional single mode lasers. These conventional single mode lasers typically have a height of 3 microns, a width of 10 microns, and a cavity length of a few millimeters. However, as noted these conventional single mode lasers produce nearly diffraction limited beams.

One or more of these deficiencies have encouraged the development of solutions thereto.

### SUMMARY OF THE INVENTION

The present invention addresses one or more of the deficiencies in the prior art.

In one aspect, the present invention is directed to one or more two-dimensional periodically index-coupled Fabry Perot Lasers (“2D PIC-FLs”) with emitters having dimensions larger than the dimensions known for prior art emitters.

In one embodiment, the present invention provides a two-dimensional periodically index-coupled Fabry Perot laser that includes a substrate, a n-cladding layer disposed atop the substrate, a n-waveguide layer disposed atop the n-cladding layer, a p-waveguide layer disposed atop the n-waveguide layer, a quantum well disposed between the n-waveguide layer and the p-waveguide layer, a p-cladding layer disposed atop the p-waveguide layer, a p-contact layer disposed atop the p-cladding layer, and a two-dimensional grating layer is disposed between the p-cladding layer and the p-contact layer. The two-dimensional grating layer includes a plurality of holes arranged in a pattern with a predetermined grating period. The two-dimensional grating layer defines a first grating area beneath the p-contact layer. The two-dimensional grating layer defines a second grating area surrounding the first grating area.

In one embodiment, it is contemplated that each of the plurality of holes are filled with air.

It is also contemplated that each of the plurality of holes are filled with a semiconductor material with an index of refraction differing from an index of refraction of the two-dimensional grating layer.

Still further, each of the plurality of holes may be filled with metal.

In another contemplated embodiment, the p-contact layer defines a pumped region that generates laser light.

An absorber region may be provided that surrounds the second grating area, wherein the absorber region absorbs laser light.

It is contemplated that the predetermined grating period in the first grating zone has a first predetermined period Pₓ in a first direction and a second predetermined period P_{y} in a second direction, orthogonal to the first direction, Pₓ=P_{y}=λ₀/n, λ₀ is the wavelength in vacuum, and n is the effective index of the lasing mode.

In another arrangement, the predetermined grating period in the second grating zone has a first predetermined period Pₓ in a first direction and a second predetermined period P_{y} in a second direction, orthogonal to the first direction, Pₓ=P_{y}=λ₀/2n, λ₀ is the wavelength in vacuum, and n is the effective index of the lasing mode.

In yet another arrangement the predetermined grating period has a first predetermined period Pₓ in a first direction and a second predetermined period P_{y} in a second direction, orthogonal to the first direction, Pₓ=λ₀/n, P_{y}=λ₀/2n, λ₀ is the wavelength in vacuum, and n is the effective index of the lasing mode.

For the two-dimensional periodically index-coupled Fabry Perot laser of the present invention, the predetermined grating period may have a first predetermined period Pₓ in a first direction and a second predetermined period P_{y} in a second direction, orthogonal to the first direction, Pₓ=λ₀/2n, P_{y}=λ₀/n, λ₀ is the wavelength in vacuum, and n is the effective index of the lasing mode.

In a further contemplated embodiment of the two-dimensional periodically index-coupled Fabry Perot laser of the present invention, in at least one of the first and second grating zones, the predetermined grating period has a first predetermined period Pₓ in a first direction and a second predetermined period P_{y} in a second direction, orthogonal to the first direction, Pₓ=P_{y}=λ₀/n, λ₀ is the wavelength in vacuum, and n is the effective index of the lasing mode.

The two-dimensional periodically index-coupled Fabry Perot laser according to the present invention also may be constructed such that, in at least one of the first and second grating zones, the predetermined grating period has a first predetermined period Pₓ in a first direction and a second predetermined period P_{y} in a second direction, orthogonal to the first direction, Pₓ=λ₀/n, P_{y}=λ₀/2n, λ₀ is the wavelength in vacuum, and n is the effective index of the lasing mode.

The present invention also is contemplated to encompass a two-dimensional periodically index-coupled Fabry Perot laser where, in at least one of the first and second grating zones, the predetermined grating period has a first predetermined period Pₓ in a first direction and a second predetermined period P_{y} in a second direction, orthogonal to the first direction, Pₓ=λ₀/2n, P_{y}=λ₀/n, λ₀ is the wavelength in vacuum, and n is the effective index of the lasing mode.

The two-dimensional periodically index-coupled Fabry Perot laser according to the present invention is contemplated to encompass an arrangement where, in the first grating zone, the predetermined grating period has a first predetermined period Pₓ in a first direction and a second predetermined period P_{y} in a second direction, orthogonal to the first direction, Pₓ=P_{y}=λ₀/n, λ₀ is the wavelength in vacuum, and n is the effective index of the lasing mode. In the second grating zone, the predetermined grating period has a third predetermined period Pₓ in a first direction and a fourth predetermined period P_{y} in the second direction, and Pₓ=P_{y}=λ₀/n.

The two-dimensional periodically index-coupled Fabry Perot laser according to that present invention also may be constructed so that, in the first grating zone, the predetermined grating period has a first predetermined period Pₓ in a first direction and a second predetermined period P_{y} in a second direction, orthogonal to the first direction, Pₓ=P_{y}=λ₀/n, λ₀ is the wavelength in vacuum, and n is the effective index of the lasing mode. In the second grating zone, the predetermined grating period has a third predetermined period Pₓ in a first direction and a fourth predetermined period P_{y} in the second direction, and Pₓ=P_{y}=λ₀/2n.

Other features and advantages of the present invention will be made apparent from the discussion that follows.

### BRIEF DESCRIPTION OF THE DRAWINGS

The present invention is described in connection with the drawing appended hereto, in which:

FIG. 1 is a perspective, graphical illustration of an edge emitting semiconductor laser having a construction known in the prior art;

FIG. 2 is a graphical, cross-sectional view of the prior art semiconductor laser illustrated in FIG. 1;

FIG. 3 is a cross-sectional, graphical illustration of a first contemplated embodiment of a two-dimensional periodically index-coupled Fabry Perot Lasers (“2D PIC-FL”) accordingly to the present invention;

FIG. 4 is a graph plotting the value of Pₓ as a function q for a case where a wavelength, λ, of the laser light is 143 nm;

FIG. 5 is a graph plotting the value of Z_{T} as a function of Pₓ for the case where λ=143 nm;

FIG. 6 is a graphical illustration of an index modulation pattern applicable to a two-dimensional grating layer that is contemplated for use in one embodiment of a 2D PIC-FL according to the present invention;

FIG. 7 graphically illustrates eight variations of different shapes of holes that may be provided in the semiconductor material that may be employed for the two-dimensional grating layer incorporated into the 2D PIC-FL of the present invention;

FIG. 8 is a graphical, top view of one contemplated configuration for a two-dimensional grating layer contemplated for incorporation into the 2D PIC-FL of the present invention;

FIG. 9 is an illustration depicting the two-dimensional grating layer shown in FIG. 8 together with an expanded view of a portion of the two-dimensional grating layer and a representation of a light intensity distribution pattern therein;

FIG. 10 is a graphical representation of the two-dimensional grating layer shown in FIG. 9, providing graphical representations of the index of refraction modulation (which ensues in modulation of laser light intensity inside the cavity), depicted as square functions, in various regions of the two-dimensional grating layer according to one embodiment of the present invention;

FIG. 11 provides a graphical representation of four plots that illustrate non-square index of refraction functions contemplated to be exhibited by one or more two-dimensional grating layers according to contemplated embodiments of the present invention;

FIG. 12 is a graphical representation of another contemplated embodiment of a two-dimensional grating layer according to the present invention;

FIG. 13 is a graphical representation of yet another contemplated embodiment of a two-dimensional grating layer according to the present invention;

FIG. 14 is a graphical representation of a further contemplated embodiment of a two-dimensional grating layer according to the present invention;

FIG. 15 is a graphical, top view of a 2D PIC-FL according to one embodiment of the present invention;

FIG. 16 is a graphical, top view of a 2D PIC-FL according to another embodiment of the present invention; and

FIG. 17 is a graphical, top view of a 2D PIC-FL according to a further embodiment of the present invention.

### DETAILED DESCRIPTION OF EMBODIMENT(S) OF THE INVENTION

The present invention will now be described in connection with several examples and embodiments. The present invention should not be understood to be limited solely to the examples and embodiments discussed. To the contrary, the discussion of selected examples and embodiments is intended to underscore the breadth and scope of the present invention, without limitation. As should be apparent to those skilled in the art, variations and equivalents of the described examples and embodiments may be employed without departing from the scope of the present invention.

In addition, aspects of the present invention will be discussed in connection with specific materials and/or components. Those materials and/or components are not intended to limit the scope of the present invention. As should be apparent to those skilled in the art, alternative materials and/or components may be employed without departing from the scope of the present invention.

In the illustrations appended hereto, for convenience and brevity, the same reference numbers are used to refer to like features in the various examples and embodiments of the present invention. The use of the same reference numbers for the same or similar structures and features is not intended to convey that each element with the same reference number is identical to all other elements with the same reference number. To the contrary, the elements may vary from one embodiment to another without departing from the scope of the present invention.

Still further, in the discussion that follows, the terms “first,” “second,” “third,” etc., may be used to refer to like elements. These terms are employed to distinguish like elements from similar examples of the same elements. For example, one fastener may be designated as a “first” fastener to differentiate that fastener from another fastener, which may be designated as a “second fastener.” The terms “first,” “second,” “third,” are not intended to convey any particular hierarchy between the elements so designated.

It is noted that the use of “first,” “second,” and “third,” etc., is intended to follow common grammatical convention. As such, while a component may be designated as “first” in one instance, that same component may be referred to as “second, “third,” etc., in a separate instance. The use of “first,” “second,” and “third,” etc., therefore, is not intended to limit the present invention.

As used in this application and in the claims, the singular forms “a,” “an,” and “the” include the plural forms unless the context clearly dictates otherwise. Additionally, the term “includes” means “comprises.” Further, the term “coupled” does not exclude the presence of intermediate elements between the coupled items. The systems, apparatus, and methods described herein should not be construed as limiting in any way. Instead, the present disclosure is directed toward all novel and non-obvious features and aspects of the various disclosed embodiments, alone and in various combinations and sub-combinations with one another. The term “or” refers to “and/or,” not “exclusive or” (unless specifically indicated).

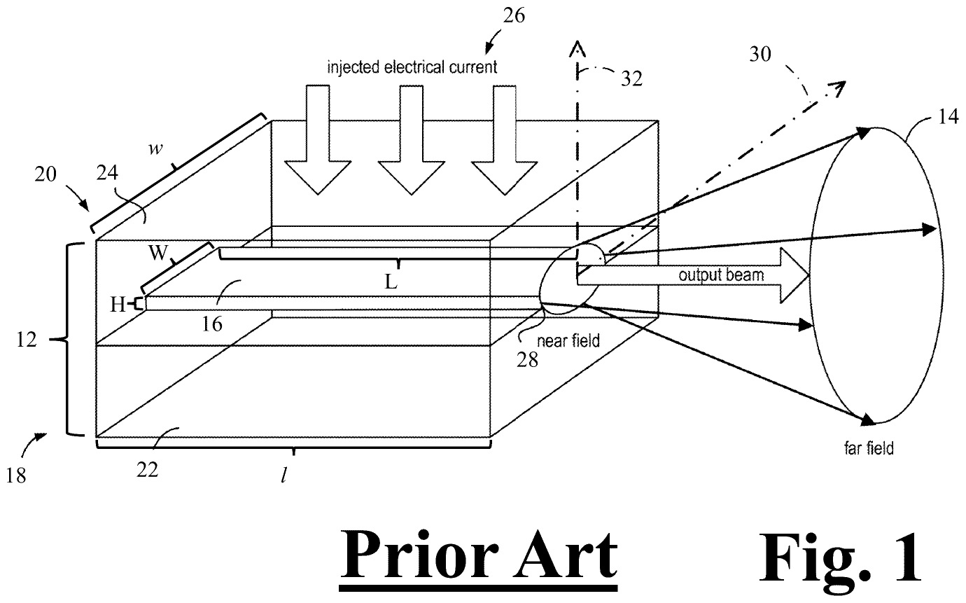

By way of introduction to various aspects of the present invention, FIG. 1 is a perspective, illustration of an edge emitting semiconductor laser 10 with a construction known to those skilled in the art.

The conventional edge emitting semiconductor laser 10 includes a waveguide 12 that emits laser light 14 from an active layer 16 that has a width W, a height H, and a length L. The waveguide 12 defines an n-side 18 and a p-side 20. The n-side 18 includes an n-waveguide layer 22. The p-side 20 includes a p-waveguide layer 24.

When an electrical current 26 is injected into the waveguide 12, the active layer 16 (also referred to as the quantum well 16) generates the laser light 14, which is emitted from a front facet 28 (also referred to as a front face 28).

A slow axis 30 and a fast axis 32 of the laser light 14 also are illustrated. The slow axis 30 refers to the axis that is parallel to and extends along the width W direction of the active layer 16. The fast axis 32 is parallel to and extends along the height H direction of the active layer 16.

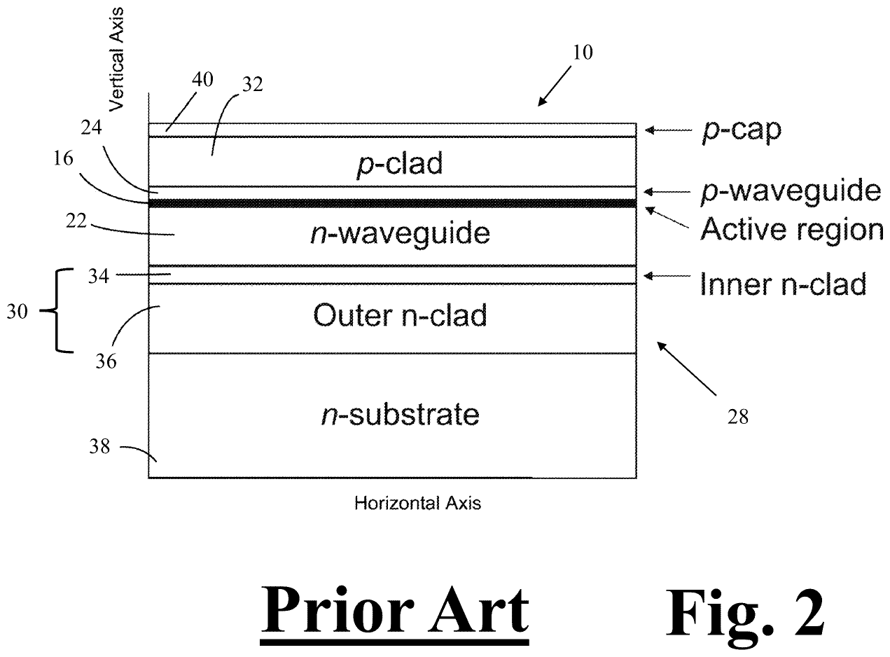

FIG. 2 is a graphical, cross-sectional view of the semiconductor laser 10 illustrated in FIG. 1.

FIG. 2 provides additional details concerning the conventional semiconductor laser 10.

In this view, an n-cladding layer 30 is illustrated below the n-waveguide layer 22. A p-cladding layer 32 is disposed above the p-waveguide layer 24. Here, the n-cladding layer 30 includes an inner n-cladding layer 34 and an outer n-cladding layer 36.

The semiconductor laser 10 also includes an n-substrate 38 (also referred to as a substrate 38) below the n-cladding layer 30. A p-cap layer 40 is disposed atop the p-cladding layer 32.

As should be apparent to those skilled in the art, when a current is applied to the p-cap layer 40, the active layer 16 generates the laser light 14.

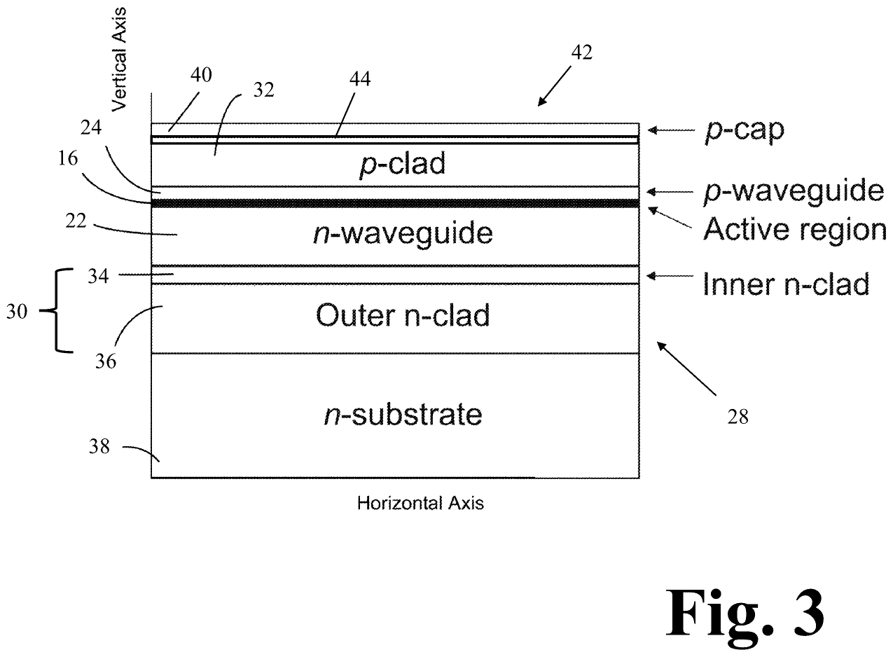

FIG. 3 is a cross-sectional, graphical illustration of a first contemplated embodiment of the two-dimensional periodically index-coupled Fabry Perot Lasers (“2D PIC-FL”) 42 accordingly to the present invention.

The 2D PIC-FL 42 shares many of the constructional details as the semiconductor layer 10 illustrated in FIGS. 1 and 2. Accordingly, like reference numbers are employed to refer to like features.

The 2D PIC-FL 42 includes an n-substrate 38, an n-cladding layer 30, an n-waveguide layer 22, an active layer 16, a p-waveguide layer 24, a p-cladding layer 32, and a p-cap layer 40.

The 2D PIC-FL 42 differs from the semiconductor laser 10 in that the 2D PIC-FL 42 includes, among other features as discussed more fully herein, a two-dimensional grating layer 44 disposed between the p-contact layer 40 and the p-cladding layer 32.

The following summary provides details for various embodiments and variations for the construction of the two-dimensional grating layer 44 that is incorporated into the 2D PIC-FL 42 of the present invention.

In the 2D PIC-FL 42 of the present invention, selected, periodic boundary conditions are set so that a light intensity u₀(x) satisfies several conditions.

First, the Rayleigh diffraction theory of light shows that there is a location in the propagating z-direction this defined according to the following equation:

$${Z}_{T} = \frac{λ}{\{ 1 - ( \sqrt{1 - {( \frac{λ}{{P}_{x}} )}^{2}} ) \}}$$

Under this theory, the plane waves emanating from a periodic function u₀(x)=u₀(x+Pₓ), with a period, Pₓ, in the x-direction, at a location x in the x-direction, and located at z=0, will be replicated at a distance Z_{T}. The periodic function, u₀(x)=u₀(x+Px), refers to the modulation of the light amplitude in the x-direction, which is induced by modulation in the refractive index. Notably, if Z_{T}=λ/q, where q is a number, it becomes possible to solve for Px in terms of λ and q as set forth in the following equation:

$${P}_{x} = \frac{λ}{\{ ( \sqrt{q ( 2 - q )} ) \}}$$

From this, the value of q is defined as a value that is less than 2 and greater than 0 for a physical system. In other words, for one contemplated embodiment of the present invention, 0<q<2. As should be apparent to those skilled in the art, λ is the length of the wave of laser light inside the cavity.

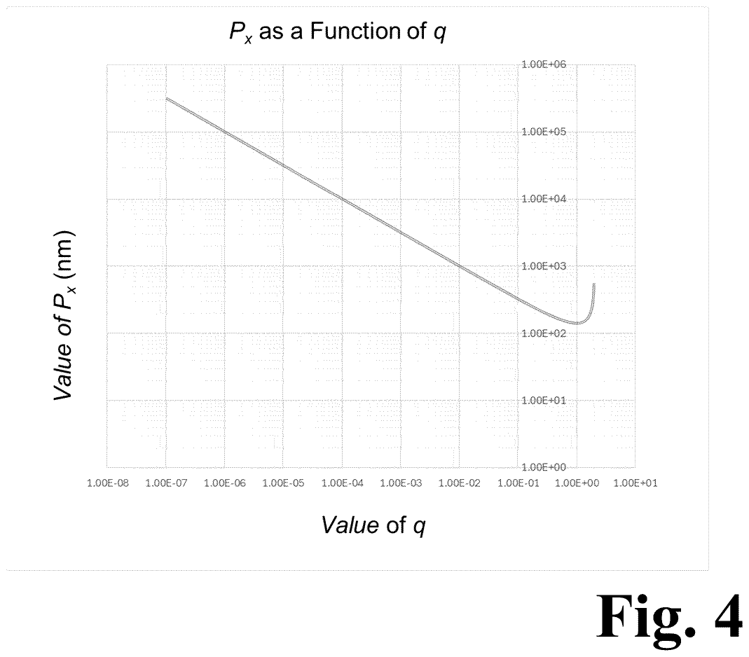

Second, with respect to the Rayleigh diffraction theory of light, the period, Pₓ may be plotted graphically as a function of q for the case where the length of the wave inside of the cavity, λ, of the laser light 14 is 143 nm. This graphical plot is provided logarithmically in FIG. 4.

While design of the periodic function Pₓ may assume any periodicity that meets the condition 0<q<2, when the value of q approaches 2, i.e., Z_{T}~λ/2, the value of Pₓ becomes infinitely large and, therefore, not meaningful. Accordingly, designs where q>2 are not physically viable and, therefore, such designs are not desirable and/or practicable.

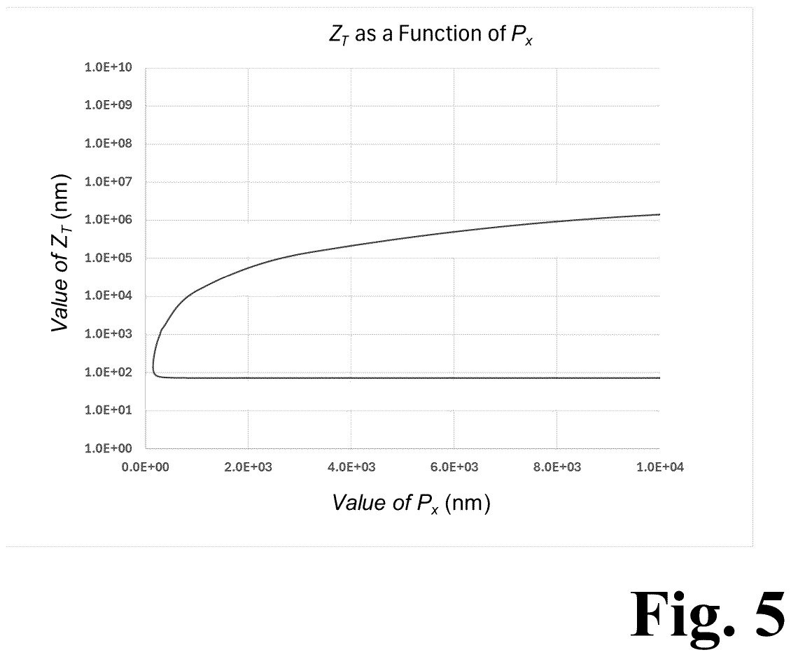

In connection with this, FIG. 5 provides a graphical plot of the value of Z_{T} as a function of Pₓ for the case where λ=143 nm.

Third, with respect to the Rayleigh diffraction theory of light, the graphical plot provided by FIG. 5 illustrates that it is not possible to achieve values smaller than Z_{T}=λ/2, i.e., 71.5 nm when λ=143 nm. From this, it is contemplated that design considerations lead to the creation of a two-dimensional grating layer 44 where Z_{T}=λ/q and where 0<q<2.

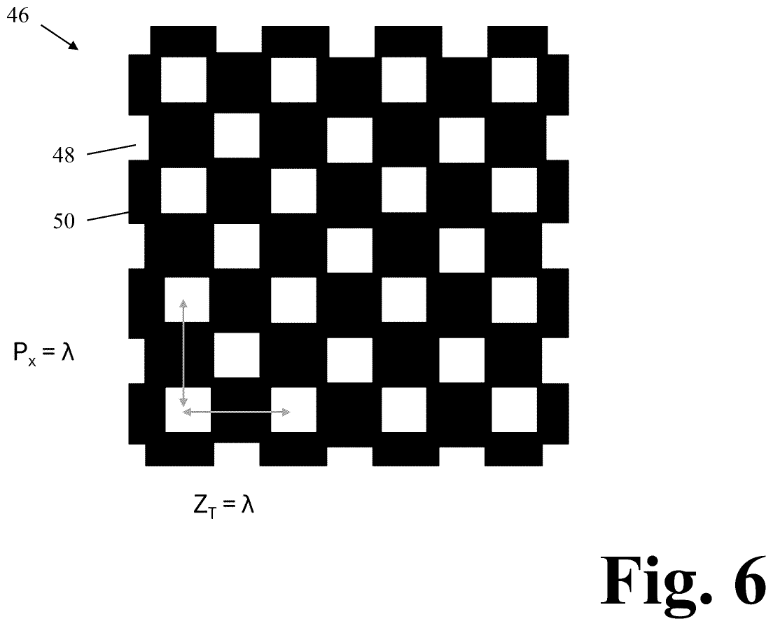

As should be apparent to those skilled in the art, when q=1, Z_{T}=λ, and Pₓ=λ, a stable design criteria is defined. In this stable design case, the index modulation pattern appears as illustrated in FIG. 6. This stable design case may be employed to construct one or more embodiments of the two-dimensional grating layer 44.

It is noted that it becomes exceedingly difficult to reduce losses due to imperfections and scattering when the value of q is close to 0 or 2. Therefore, for purpose of the present invention, devices with 1×10⁻³<q<2 are most likely to have the lowest losses due to the fact that fewer fabrication artifacts are likely to be introduced. Moreover, the diffracted beam propagates over short distances that are on the order of the wavelength of light so that maximum coherence is maintained.

In further connection with the general design criteria for constructing a two dimensional grating layer 44, one embodiment of the present invention contemplates use in an environment with a monochromatic wave field having a vacuum wavelength, λ₀, and a wavelength, λ, in the laser medium forming the two dimensional grating layer 44. Here, for instance, a lateral (slow-axis direction) periodic structure with an index modulation of refraction with a period, Pₓ, may be chosen such that a periodic structure is formed in the longitudinal direction (propagation direction or z-direction) with a period Z_{T}.

Relying on the parameters identified herein, a two-dimensional grating layer 46 may be constructed with a repeating pattern of squares as illustrated in FIG. 6. Here, the pattern includes holes (or openings) 48 that are provided in the semiconductor material 50 having the illustrated pattern. It is noted that the semiconductor material 50 is contemplated to be a material with a predetermined index of refraction, as should be apparent to those skilled in the art.

It is noted that, while the holes 48 are illustrated as being square in shape, the present invention is not limited solely to holes 48 that are square in shape. To the contrary, the holes 48 may be of any suitable shape.

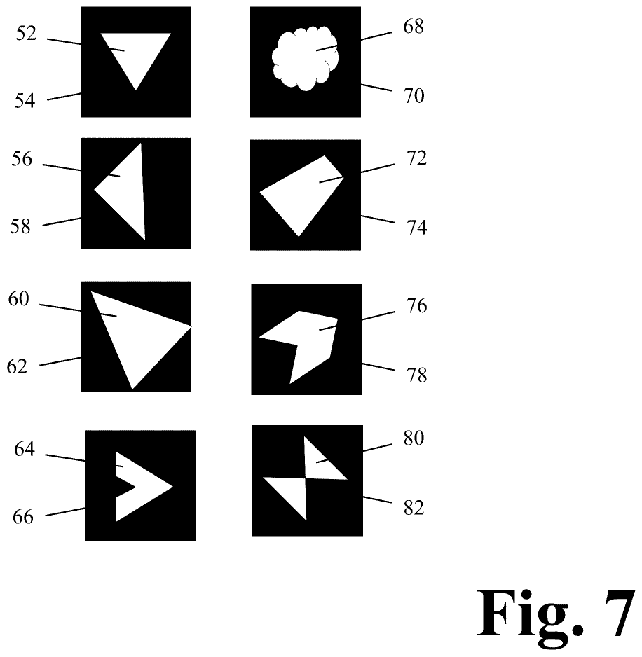

FIG. 7 illustrates eight examples of holes 52, 56, 60, 64, 68, 72, 76, 80 in the semiconductor material 54, 58, 62, 66, 70, 74, 78, 82 that may be employed for the two-dimensional grating layer 44, 46 according to the present invention.

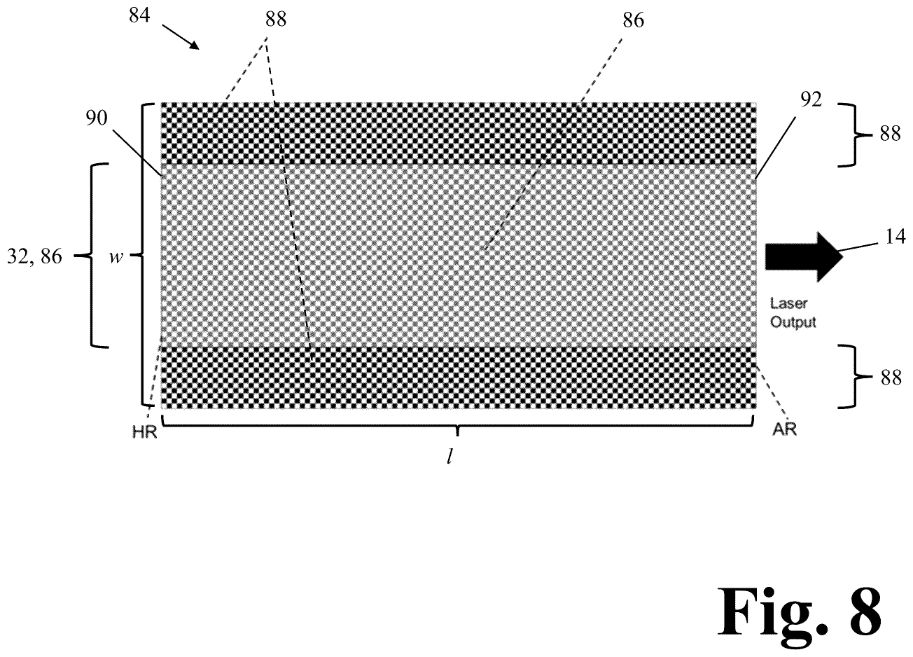

FIG. 8 is a graphical, top view of one contemplated configuration for a two-dimensional grating layer 84 according to the present invention as might be implemented in the 2D PIC-FL 42, for example, as shown in FIG. 3. For ease of reference, the two-dimensional grating layer 84 is contemplated to have the same width w and the same length/as the 2D PIC-FL 42. In other words, to facilitate discussion of the two-dimensional grating layer 84, the two-dimensional grating layer 84 is configured to cover the entire surface of the p-cladding layer 32 illustrated in FIG. 3.

In FIG. 8, the pattern of the holes in the semiconductor material is contemplated to be consistent with the pattern illustrated in FIG. 6, for example. Here, there are two zones that are defined for the 2D PIC-FL 42. The first zone is referred to as the pumped zone 86. The second zone is referred to as the unpumped zone 88. As should be apparent to those skilled in the art, the pumped zone 86 lies beneath the p-cladding layer 32. The unpumped zone 88 is defined as the areas on either side of the p-cladding layer 32. When the current 26 is applied to the p-cladding layer 32, the active layer 16 generates the laser light 14 within the area referred to as the pumped zone 86. Laser light is not generated in the unpumped zone 88.

FIG. 8 also illustrates the high reflection (“HR”) facet 90 that reflects all (or nearly all) of the laser light generated by the active region 16. The anti-reflection (“AR”) facet 92 is only partially reflective, permitting the laser light 14 to be emitted from the active layer 16 as shown.

With continued reference to FIG. 8, it is contemplated that the two-dimensional grating layer 84 has a uniform pattern of holes in the pumped zone 86 and in the unpumped zone 88.

The pattern of the holes in the two-dimensional grating layer 84 illustrated in FIG. 8 may be mathematically expressed as:

$${u}_{0} ( x ) = {u}_{0} ( x + Px ) = > {u}_{z} ( x ) = {u}_{z + zT} ( x )$$

This expression describes the fact that a periodic function of light located at a position, x, is replicated after propagating in the z-direction for a distance of Z_{T}. Specifically, the periodic function, u₀(x)=u₀(x+Px), refers to the modulation of the light amplitude in the x-direction, which is induced by modulation in the refractive index. Those skilled in the art further may refer to it as periodic light intensity amplitude function in the x-direction. Px is the period of light intensity modulation.

As should be apparent to those skilled in the art, the function u₀(x) is phase shifted by a value of π (180 degrees) at every separation distance of Z_{T}/2 and self-replicates at every distance Z_{T}. In connection with this relationship, reference is made again to FIG. 5.

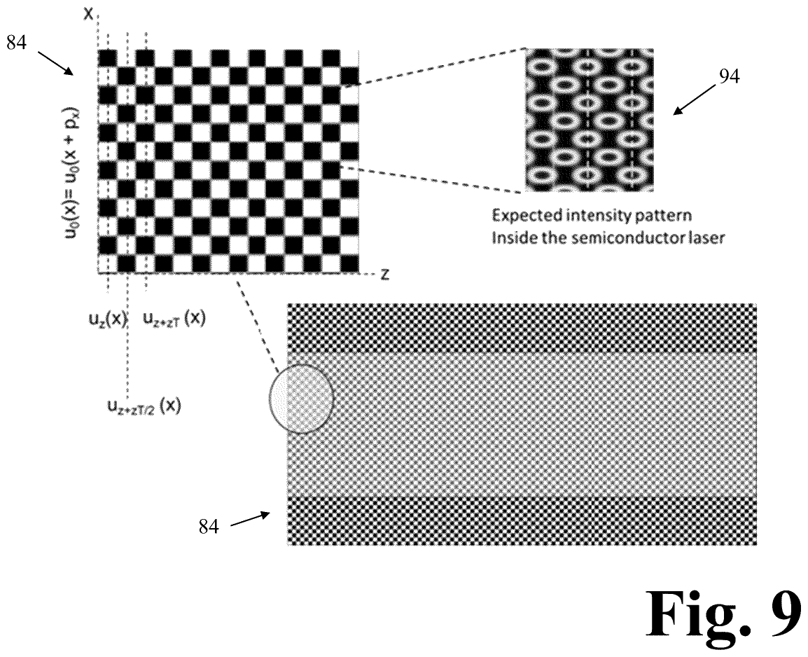

FIG. 9 is an illustration that shows the two-dimensional grating layer 84 from FIG. 8. FIG. 9 also includes an expanded view of a portion of the two-dimensional grating layer 84. In addition, an expected light intensity pattern 94 for the light inside of the 2D PIC-FL 42 also is depicted.

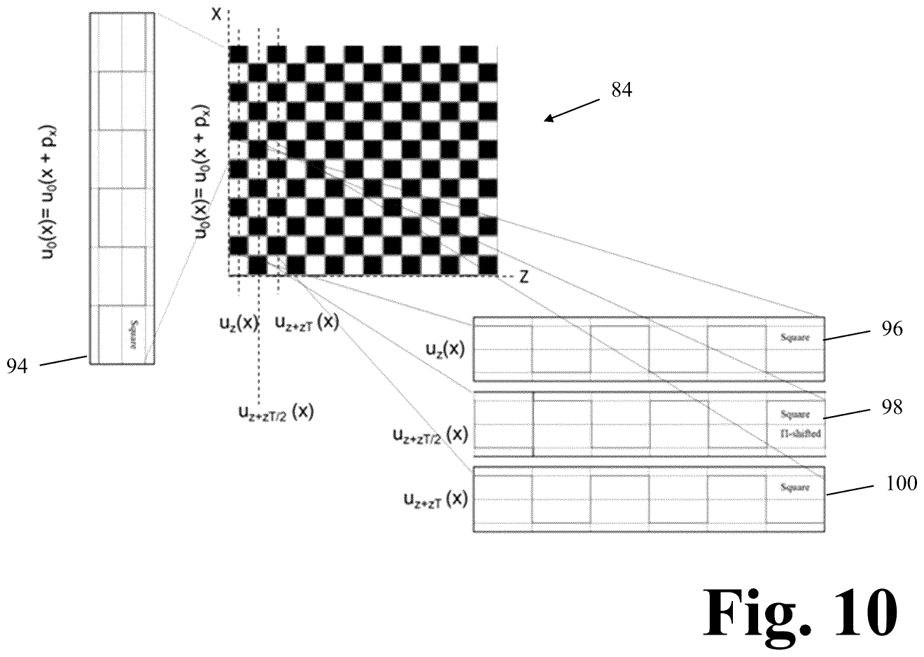

FIG. 10 is another graphical representation of the two-dimensional grating layer 84. Here, the intensities of the index of refraction modulation in various regions of the two-dimensional grating layer 84 are illustrated in graphical format. Specifically, the indices of refraction modulation are shown by the square function diagrams 94, 96, 98, 100. It is noted that these functions 94, 96, 98, 100 are merely exemplary of the index modulation for one possible configuration for the two-dimensional grating layer 84.

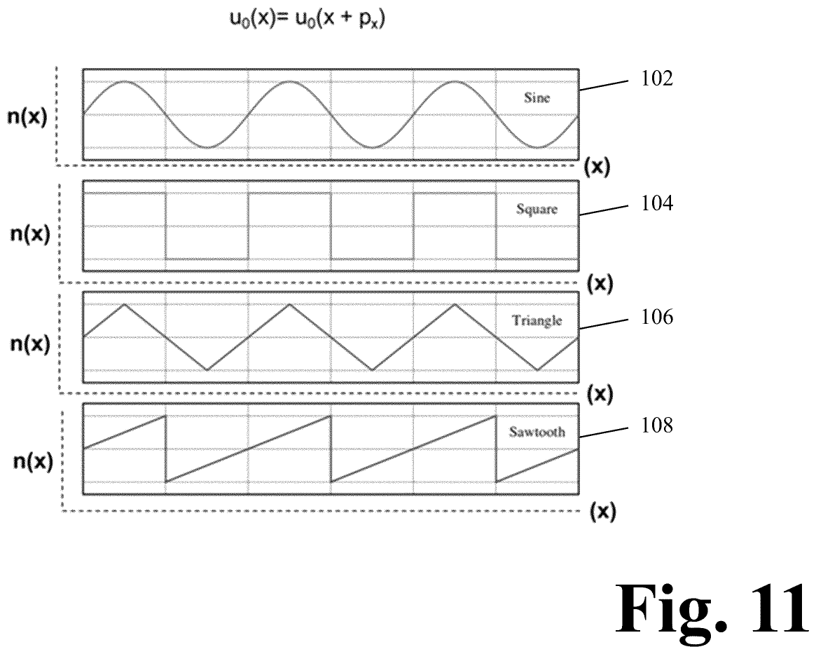

FIG. 11 provides four additional plots that illustrate non-square functions 102, 104, 106, 108 for index modulation that may be exhibited by one or more two-dimensional grating layers according to the present invention. Specifically, FIG. 11 illustrates a sine function 102, a square function 104 (akin to the square functions 94, 96, 98, 100 shown in FIG. 10), a triangle function 106, and a sawtooth function 108. Again, these functions are merely illustrative, non-limiting functions for the index modulation that may be embodied by one or more embodiments of the 2D PIC-FL 42 of the present invention.

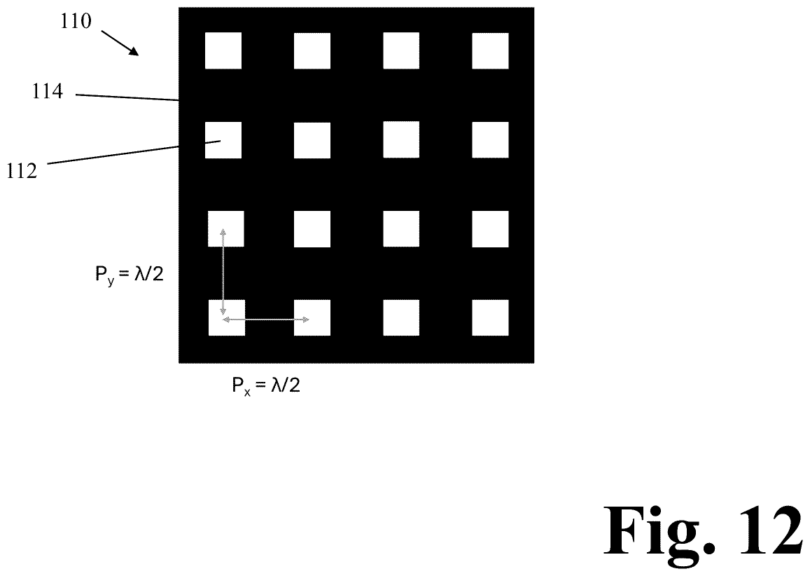

FIG. 12 is a graphical representation of another contemplated two-dimensional grating layer 110 according to the present invention. In this embodiment, the holes 112 in the semiconductor material 114 are square in shape. Here, the pattern of holes 112 are arranged such that the index modulation pattern has the following prescription: Pₓ=P_{y}=λ/2, where λ₀ is the wavelength of the laser light 14 in a vacuum, where λ is the wavelength of the laser light 14 in the laser medium, where n is the effective index of the mode, and where λ=λ₀/n.

While the holes illustrated in FIG. 12 are shown as being square in shape, the holes 112 may have any other shape including round, triangular, oval, and asymmetric, as discussed in further detail herein.

In further connection with FIG. 12, it is noted that a fill-factor, which is defined as a ratio of the cross-sectional area of the pattern compared to the unit cell area, i.e., (Pₓ×P_{y}) may be in a range of 0.15 to 0.6.

In the embodiment illustrated in FIG. 12, it is contemplated that the holes 112 are not filled with any material. Here, the holes may be filled with air, for example.

Other examples of the two-dimensional grating 110 are contemplated to encompass edge-emitting Fabry Perot lasers. In these example, the two-dimensional grating layer 110 may include holes 112 filled with metal. In another example, the holes 112 may be filled with a semiconductor material having an index of refraction that differs from the index of refraction of the semiconductor material 114. In still another contemplated example, the two-dimensional grating layer 110 may have a semiconductor material in the holes 112 with a p-contact layer disposed atop the semiconductor material in the holes 112. In yet another contemplated embodiment, the holes 112 may be filled with an oxide.

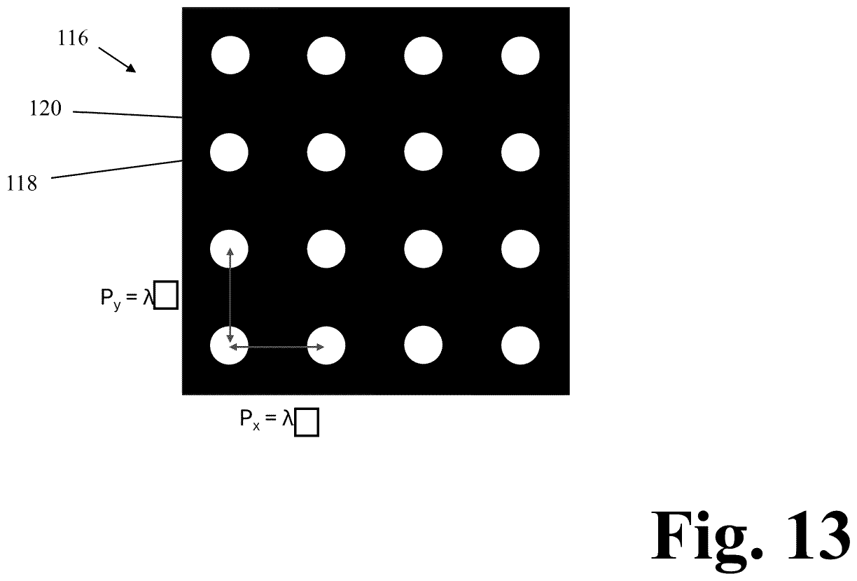

FIG. 13 is a graphical illustration of a further contemplated embodiment of a two-dimensional grating layer 116 according to the present invention. Here, the holes 118 in the semiconductor material 120 are circular in shape. In addition, the holes 118 are disposed in the semiconductor material 118 such that Pₓ=P_{y}=λ.

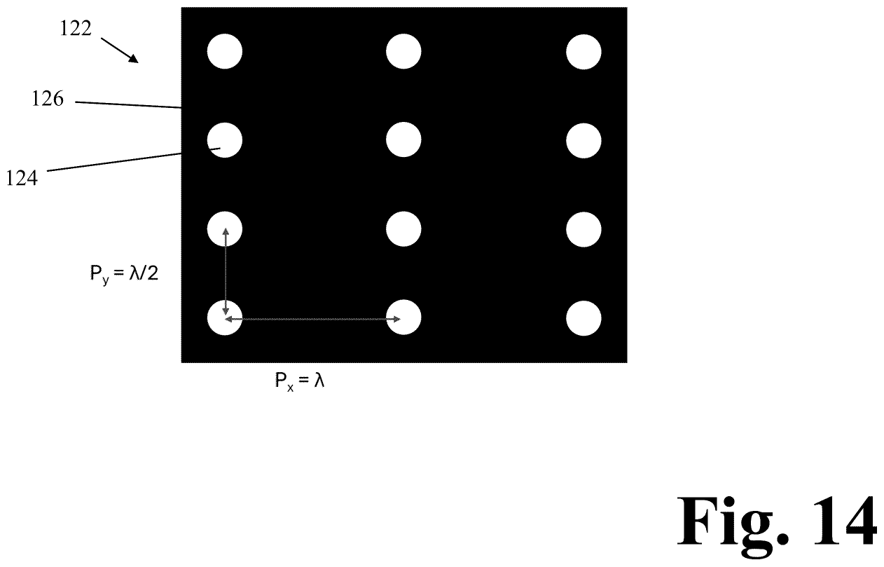

FIG. 14 is a graphical illustration of a further contemplated embodiment of a two-dimensional grating layer 122 according to the present invention. Here, the holes 124 in the semiconductor material 126 are circular in shape. In addition, the holes 124 are disposed in the semiconductor material 126 such that Pₓ=λ and P_{y}=λ/2. Alternatively, the holes 124 may be arranged such that Pₓ=λ/2 and P_{y}=λ.

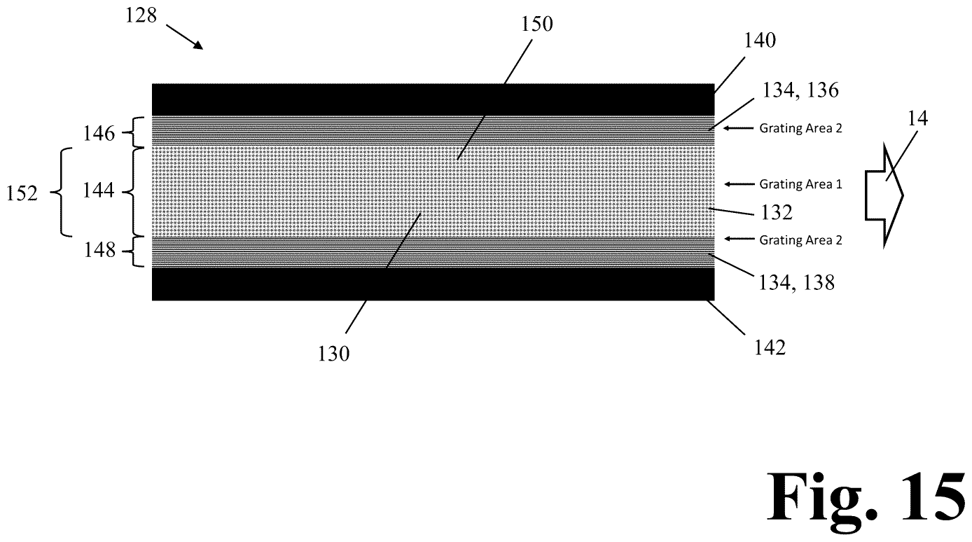

FIG. 15 is a graphical, top view of an embodiment of a 2D PIC-FL 128 according to an embodiment of the present invention. Here the two-dimensional grating layer 130 defines a first grating area 132 and a second grating area 134. The first grating area 132 is contemplated to have a pattern of holes that is consistent with, for example, the patterns illustrated in one of FIGS. 6, 7, 9, 12, 13, and 14. The second grating area 134 is contemplated to have a pattern of holes that differs from the first grating area 132. However, the first and second grating areas 132, 134 may have the same pattern of holes without departing from the scope of the present invention.

As shown in FIG. 15, the first grating area 132 extends along the longitudinal direction of the 2D PIC-FL 128. The second grating area 134 extends along both sides of the first grating area 132. As illustrated, the second grating area 134 includes a first strip 136 disposed along one edge of the first grating area 132 and a second strip 138 disposed along the other edge of the first gating area 132.

On either side of the second grating area 134, the 2D PIC-FL 128 includes a first absorber region 140 and a second absorber region 142. The first absorber region 140 and the second absorber region 142 are contemplated to be made from one or more materials that absorb the laser light 14.

As illustrated in FIG. 15, the first grating area 132 has a first width 144. The first strip 136 has a second width 146, and the second strip 138 has a third width 148. For the 2D PIC-FL 128, the p-contact layer 150 has a fourth width 152. Here, the fourth width 152 of the p-contact layer 150 is equal to the first width 144 of the first grating area 132.

For the 2D PIC-FL 128, when a current 26 is applied to the p-contact layer 150, the laser light 14 is generated in the region commensurate with the p-contact layer 150. As a result, the area of the 2D PIC-FL 128 that is consistent with the p-contact layer 150 is referred to as the pumped region (or pumped zone), as discussed hereinabove.

The second grating area 134 is constructed so that the holes in the semiconductor material reflect light from the second grating area 134 back into the first grating area 132.

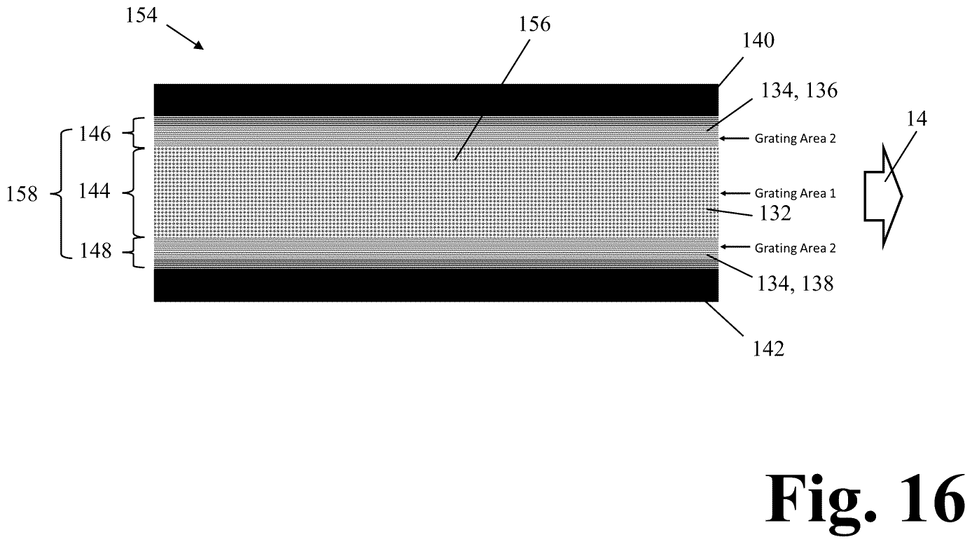

FIG. 16 is a graphical, top view of another 2D PIC-FL 156 according to the present invention. In this embodiment, the p-contact layer 156 is wider than the first gating area 132 illustrated in FIG. 15. Specifically, the p-contact layer 156 has a fifth width 158 that extends into the second grating area 134 on either side of the first grating area 132.

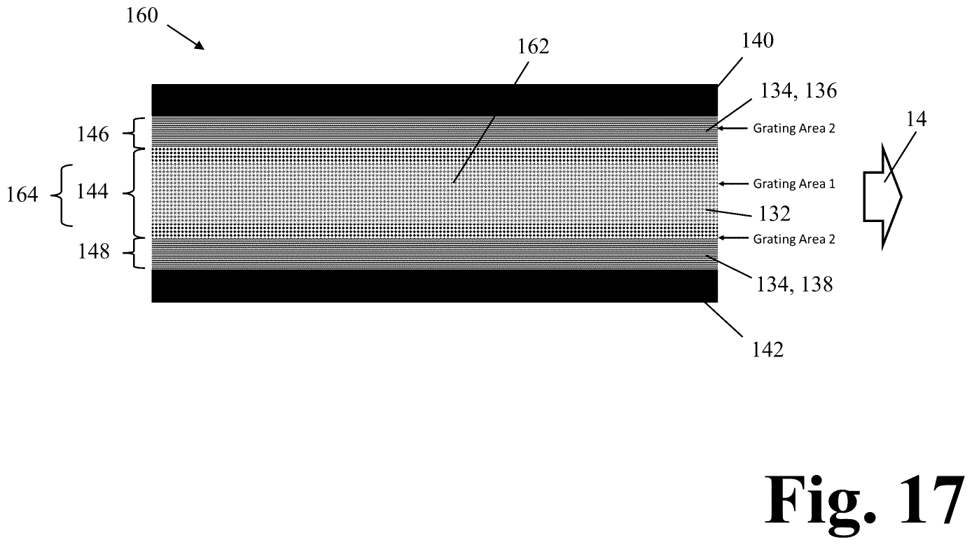

FIG. 17 is a graphical, top view of another 2D PIC-FL 160 according to the present invention. In this embodiment, the p-contact layer 162 is narrower than the first gating area 132 illustrated in FIG. 15. Here, the p-cladding layer 162 has a sixth width 164 that is contained within the boundaries of the first grating area 132.

In connection with the various embodiments of the present invention, it is noted that the 2D PIC-FL 42, 128, 154, 160 may be manufactured using any of a number of techniques known to those skilled in the art.

In a first example, the structure of the 2D PIC-FL 42, 128, 154, 160 is partly grown. Using a lithographic process such as an e-beam, laser holography, and/or nano-imprint technology (e.g., nano-imprint lithography (“NIL”)), a mask (not shown) with the desired two-dimensional pattern for the two-dimensional grating layer 44, 46, 84, 110, 116, 122, 130 is formed atop the p-cladding layer 32. Using this mask, the underlying semiconductor surface is etched and another semiconductor material with a higher or a lower index of refraction is subsequently grown to form one of the two-dimensional grating layers 44, 46, 84, 110, 116, 122, 130. The index modulation pattern for the two-dimensional grating layer 44, 46, 84, 110, 116, 122, 130 is contemplated to be formed on the entire surface of the p-cladding layer 32 of the 2D PIC-FL 42, 128, 154, 160. However, the laser light 14 is contemplated to be generated only in the pumped zone 86 where the electrical current 26 is applied.

In another contemplated manufacturing process, the structure of the 2D PIC-FL 42, 128, 154, 160 is fully grown. Using lithographic process such as an e-beam, laser holography, or nano-imprint technology (e.g., nano-imprint lithography (“NIL”)), a mask (not shown) with the desired two-dimensional pattern for the two-dimensional grating layer 44, 46, 84, 110, 116, 122, 130 is formed atop the p-cladding layer 32. Using this mask, the underlying semiconductor surface is etched down and a metal, such as gold or copper (or any other suitable metal), is deposited into the holes in the two-dimensional grating layer 44, 46, 84, 110, 116, 122, 130. Here, the unpumped region 88 is contemplated to include an interposing dielectric to prevent any electrical contact to the index modulated areas. Moreover, the unpumped region 88 is contemplated to have a Schottky contact whereas the pumped region 86 is contemplated to have an Ohmic contact.

Alternatively, the structure of the 2D PIC-FL 42, 128, 154, 160 may be grown using a lithographic process such as an e-beam, laser holography, or nano-imprint technology (e.g., nano-imprint lithography (“NIL”)), via a mask with the desired pattern for the two-dimensional grating layer 44, 46, 84, 110, 116, 122, 130. In this contemplated embodiment, the underlying semiconductor surface is etched down and oxides such as silicon-dioxide, aluminum-oxide, silicon-nitride (or any other dielectric material) may be deposited into the holes in the two-dimensional grating layer 44, 46, 84, 110, 116, 122, 130. In this contemplated embodiment, the unpumped zone 88 is contemplated to have an interposing dielectric to prevent any electrical contact to the index modulated areas. The unpumped zone 88 may have, for example, a Schottky contact while the pumped region 86 has an Ohmic contact.

Other advantages of the present invention will be apparent to those skilled in the art.

In view of the many possible embodiments to which the principles of the disclosed technology may be applied, it should be recognized that the illustrated embodiments are only preferred examples and should not be taken as limiting the scope of the disclosure. Variations and equivalents known to those skilled in the art also are contemplated to fall within the scope of the present invention.

1. A two-dimensional periodically index-coupled Fabry Perot laser, comprising:
a substrate;
a n-cladding layer disposed atop the substrate;
a n-waveguide layer disposed atop the n-cladding layer;
a p-waveguide layer disposed atop the n-waveguide layer;
a quantum well disposed between the n-waveguide layer and the p-waveguide layer;
a p-cladding layer disposed atop the p-waveguide layer;
a p-contact layer disposed atop the p-cladding layer; and
a two-dimensional grating layer is disposed between the p-cladding layer and the p-contact layer,
wherein the two-dimensional grating layer comprises a plurality of holes arranged in a pattern with a predetermined grating period,
wherein the two-dimensional grating layer defines a first grating area beneath the p-contact layer, and
wherein the two-dimensional grating layer defines a second grating area surrounding the first grating area.

2. The two-dimensional periodically index-coupled Fabry Perot laser according to claim 1, wherein each of the plurality of holes are filled with air.

3. The two-dimensional periodically index-coupled Fabry Perot laser according to claim 1, wherein each of the plurality of holes are filled with a semiconductor material with an index of refraction differing from an index of refraction of the two-dimensional grating layer.

4. The two-dimensional periodically index-coupled Fabry Perot laser according to claim 1, wherein each of the plurality of holes are filled with metal.

5. The two-dimensional periodically index-coupled Fabry Perot laser according to claim 1, wherein the p-contact layer defines a pumped region that generates laser light.

6. The two-dimensional periodically index-coupled Fabry Perot laser according to claim 1, further comprising an absorber region surrounding the second grating area, wherein the absorber region absorbs laser light.

7. The two-dimensional periodically index-coupled Fabry Perot laser according to claim 1, wherein:
the predetermined grating period in the first grating zone has a first predetermined period Pₓ in a first direction and a second predetermined period P_{y} in a second direction, orthogonal to the first direction,
$${P}_{x} = {P}_{y} = {λ}_{0} / n ,$$
λ₀ is the wavelength in vacuum, and
n is the effective index of the lasing mode.

8. The two-dimensional periodically index-coupled Fabry Perot laser according to claim 1, wherein:
the predetermined grating period in the second grating zone has a first predetermined period Pₓ in a first direction and a second predetermined period P_{y} in a second direction, orthogonal to the first direction,
$${P}_{x} = {P}_{y} = {λ}_{0} / 2 n ,$$
λ₀ is the wavelength in vacuum, and
n is the effective index of the lasing mode.

9. The two-dimensional periodically index-coupled Fabry Perot laser according to claim 1, wherein:
the predetermined grating period has a first predetermined period Pₓ in a first direction and a second predetermined period P_{y} in a second direction, orthogonal to the first direction,
$${P}_{x} = {λ}_{0} / n ,$$
$${P}_{y} = {λ}_{0} / 2 n ,$$
λ₀ is the wavelength in vacuum, and
n is the effective index of the lasing mode.

10. The two-dimensional periodically index-coupled Fabry Perot laser according to claim 1, wherein:
the predetermined grating period has a first predetermined period Pₓ in a first direction and a second predetermined period P_{y} in a second direction, orthogonal to the first direction,
$${P}_{x} = {λ}_{0} / 2 n ,$$
$${P}_{y} = {λ}_{0} / n ,$$
λ₀ is the wavelength in vacuum, and
n is the effective index of the lasing mode.

11. The two-dimensional periodically index-coupled Fabry Perot laser according to claim 1, wherein, in at least one of the first and second grating zones:
the predetermined grating period has a first predetermined period Pₓ in a first direction and a second predetermined period P_{y} in a second direction, orthogonal to the first direction,
$${P}_{x} = {P}_{y} = {λ}_{0} / n ,$$
λ₀ is the wavelength in vacuum, and
n is the effective index of the lasing mode.

12. The two-dimensional periodically index-coupled Fabry Perot laser according to claim 1, wherein, in at least one of the first and second grating zones:
the predetermined grating period has a first predetermined period Pₓ in a first direction and a second predetermined period P_{y} in a second direction, orthogonal to the first direction,
$${P}_{x} = {λ}_{0} / n ,$$
$${P}_{y} = {λ}_{0} / 2 n ,$$
λ₀ is the wavelength in vacuum, and
n is the effective index of the lasing mode.

13. The two-dimensional periodically index-coupled Fabry Perot laser according to claim 1, wherein, in at least one of the first and second grating zones:
the predetermined grating period has a first predetermined period Pₓ in a first direction and a second predetermined period P_{y} in a second direction, orthogonal to the first direction,
$${P}_{x} = {λ}_{0} / 2 n ,$$
$${P}_{y} = {λ}_{0} / n ,$$
λ₀ is the wavelength in vacuum, and
n is the effective index of the lasing mode.

14. The two-dimensional periodically index-coupled Fabry Perot laser according to claim 1, wherein:
in the first grating zone:
the predetermined grating period has a first predetermined period Pₓ in a first direction and a second predetermined period P_{y} in a second direction, orthogonal to the first direction,
$${P}_{x} = {P}_{y} = {λ}_{0} / n ,$$
λ₀ is the wavelength in vacuum, and
n is the effective index of the lasing mode; and
in the second grating zone:
the predetermined grating period has a third predetermined period Pₓ in a first direction and a fourth predetermined period P_{y} in the second direction, and
$${P}_{x} = {P}_{y} = {λ}_{0} / n .$$

15. The two-dimensional periodically index-coupled Fabry Perot laser according to claim 1, wherein:
in the first grating zone:
the predetermined grating period has a first predetermined period Pₓ in a first direction and a second predetermined period P_{y} in a second direction, orthogonal to the first direction,
$${P}_{x} = {P}_{y} = {λ}_{0} / n ,$$
λ₀ is the wavelength in vacuum, and
n is the effective index of the lasing mode; and
in the second grating zone:
the predetermined grating period has a third predetermined period Pₓ in a first direction and a fourth predetermined period P_{y} in the second direction, and
$${P}_{x} = {P}_{y} = {λ}_{0} / 2 n .$$
